(19) United States
(12) Patent Application Publication
(10) Pub. No.: US 2024/0291453 A1
(43) Pub. Date: Aug. 29, 2024

(54) HIGH GAIN, LOW-OFFSET, CLASS AB AMPLIFIER CIRCUIT

(71) Applicant: Snap Inc., Santa Clara, CA (US)

(72) Inventor: Stewart S. Taylor, Beaverton, OR (US)

(21) Appl. No.: 18/427,535

(22) Filed: Jan. 30, 2024

Related U.S. Application Data
(60) Provisional application No. 63/448,469, filed on Feb. 27, 2023.

(51) Int. Cl. H03F 3/45; H03G 1/00

(52) U.S. Cl. CPC H03F 3/45748; H03F 3/45219; H03F 3/45273; H03G 1/0023; H03G 1/0029; H03F 2200/375; H03F 2203/45028

(57) ABSTRACT

An amplifier circuit including a first folded double cascode stage configured to receive a differential input signal at a first pair of input transistors and generate a first drive signal, a second folded double cascode stage configured to receive the differential input signal at a second pair of input transistors and generate a second drive signal, and an output stage. The output stage includes a PMOS common-source output transistor configured to receive the first drive signal at its gate, and an NMOS common-source output transistor configured to receive the first drive signal at its gate, the PMOS common-source output transistor and NMOS common-source output transistor being jointly configured to generate an output signal based on the first drive signal and the second drive signal.

### CLAIM OF PRIORITY

This application claims the benefit of priority to U.S. Provisional Application Ser. No. 63/448,469, filed on Feb. 27, 2023, which is incorporated herein by reference in its entirety.

### BACKGROUND

Amplifiers are commonly used in a range of applications. A class AB amplifier combines features of class A amplifiers, such as low distortion of input waveforms during amplification, and class B amplifiers, such as high amplification efficiency.

### BRIEF DESCRIPTION OF THE SEVERAL VIEWS OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Some non-limiting examples are illustrated in the figures of the accompanying drawings in which:

FIG. 1 a circuit diagram showing an example amplifier circuit according to at least one example.

FIG. 2 is a circuit diagram of the left biasing block of the amplifier circuit of FIG. 1.

FIG. 3 is a circuit diagram of the right biasing block of the amplifier circuit of FIG. 1.

FIG. 4 is a circuit diagram of the first folded double cascode stage of the amplifier circuit of FIG. 1.

FIG. 5 is a circuit diagram of the second folded double cascode stage of the amplifier circuit of FIG. 1.

FIG. 6 is a circuit diagram of the output stage of the amplifier circuit of FIG. 1.

FIG. 7 illustrates a method 700 of amplifying a differential input signal in accordance with at least one example.

### DETAILED DESCRIPTION

Examples of the present disclosure provide a high voltage gain, low input offset voltage, class AB amplifier. The amplifier may be useful for various applications, including driving a capacitive load.

Examples described herein may attempt to address one or more technical problems. Some examples provide a high voltage gain amplifier, such as an amplifier with voltage amplification greater than 200,000 (Av>200,000). Some examples provide a low input offset voltage amplifier, such as an amplifier with input offset voltage less than 100 microvolts (<100 μV), or approximately 50 μV in some examples. Some examples provide an amplifier with a class AB output stage, thereby providing an output stage having low bias current (e.g., between 15 and 150 μA, such as approximately 50 μA) and large peak current capability (e.g., between 30 mA and 300 mA, such as approximately 100 mA) on demand. Some examples provide an amplifier with an equal number of gain stages for positive and negative output signals, thereby providing approximately equally high gain for both positive and negative signal swings. Some examples provide an amplifier with two high impedance nodes in the signal path, thereby facilitating easy, stable compensation and the ability to drive a large capacitive load. Some examples provide an amplifier with approximately rail-to-rail output voltage swing such as V_{DD} to ground or V_{SS} from a common source output stage (e.g., within 100 mV of rail-to-rail output voltage swing for a large load current, or within 10 mV for a small load current, approximately within 50 mV in some examples).

As used herein, the term “input offset voltage” refers to deterministic input offset voltage due to low voltage gain and imbalance, rather than random mismatch, which may be inherent to the transistors. Random mismatch will generally increase the magnitude of the overall input offset voltage of an amplifier. In some examples described herein, an amplifier circuit is provided that avoids making the total input offset voltage noticeably larger because of low voltage gain and imbalance.

Example amplifiers described herein can be implemented with either an NMOS input stage or a PMOS input stage according to the common-mode input voltage requirements. An NMOS input stage common-mode range can approach the positive supply voltage, while a PMOS input stage common-mode range can approach ground potential (e.g., 0V). In some examples, these requirements can be implemented by including two separate precision biased double folded cascode input stages to enhance or increase voltage gain prior to a common source output stage (driven by one NMOS output transistor and one PMOS output transistor). The DC voltages at the gates of the output transistors may be inherently different or unbalanced, resulting in a large input offset voltage and drift if the gain of the first stage is not sufficiently high. For class AB control of the output stage, a translinear harmonic mean regulating feedback loop may be employed in some examples.

Example amplifiers described herein may be applicable in the context of integrated circuits (ICs), and in particular, complementary metal-oxide semiconductor (CMOS) ICs. However, some examples described herein could be implemented outside of the context of CMOS ICs, such as in silicon or non-silicon bipolar technology, gallium arsenide (GaAs) semiconductors, gallium nitride (GaN) semiconductors, indium gallium phosphide (InGaP) semiconductors, or other suitable technologies.

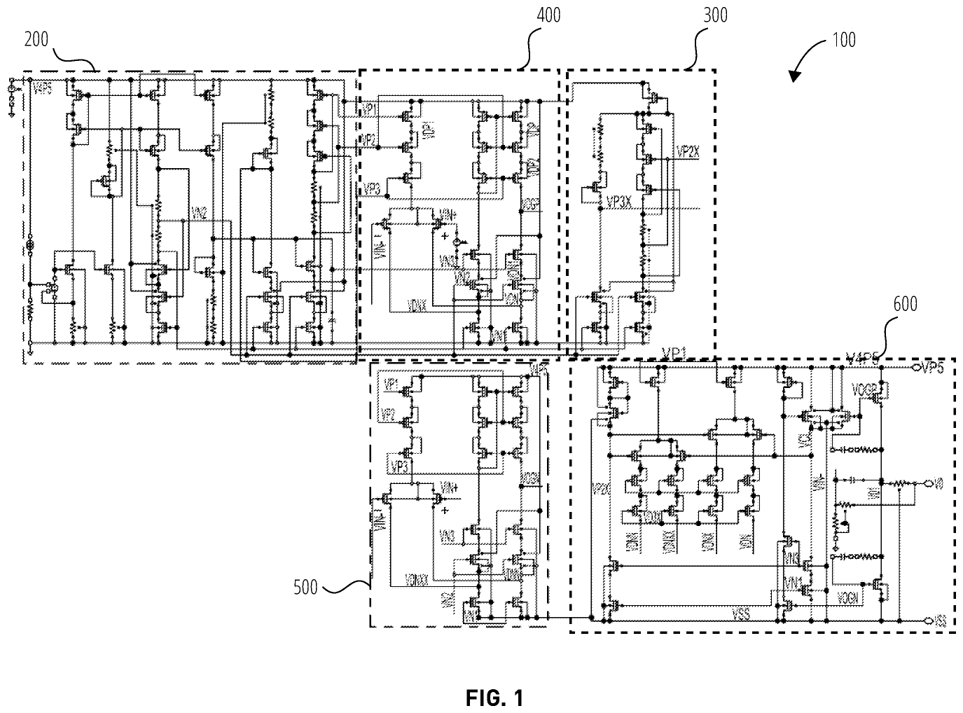

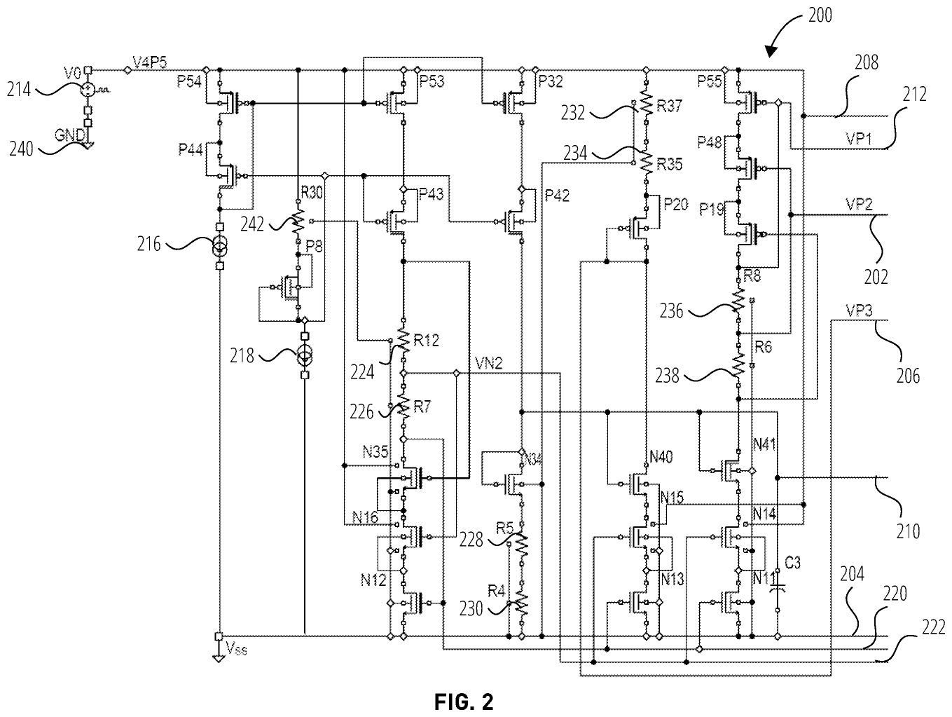

FIG. 1 shows an example amplifier circuit 100 as a block diagram. The amplifier circuit 100 includes several distinct functional blocks: a left biasing block 200, a first folded double cascode stage 400, a second folded double cascode stage 500, a right biasing block 300, and an output stage 600. Each of the illustrated functional blocks 200, 400, 500, 300, 600 is described in greater detail below with reference to circuit diagrams of example functional blocks shown in FIG. 2 through FIG. 6.

In some examples, the first folded double cascode stage 400 and second folded double cascode stage 500 are identical or near-identical P-type metal-oxide-semiconductor (PMOS) input folded double cascode stages. Each folded double cascode stage 400, 500 is coupled to a respective output transistor of the output stage 600. Thus, each folded double cascode stage 400, 500 is configured to enhance or increase voltage gain prior to a common source output stage driven by one n-channel metal-oxide semiconductor (NMOS) output transistor and one PMOS output transistor. Examples of the output stages and the output transistors are described below with reference to example output stage 600. In some examples, the output stage 600 includes the NMOS and PMOS common-source transistors coupled to a translinear harmonic mean class AB regulating loop.

FIG. 2 shows an example left biasing block 200 of the amplifier circuit 100.

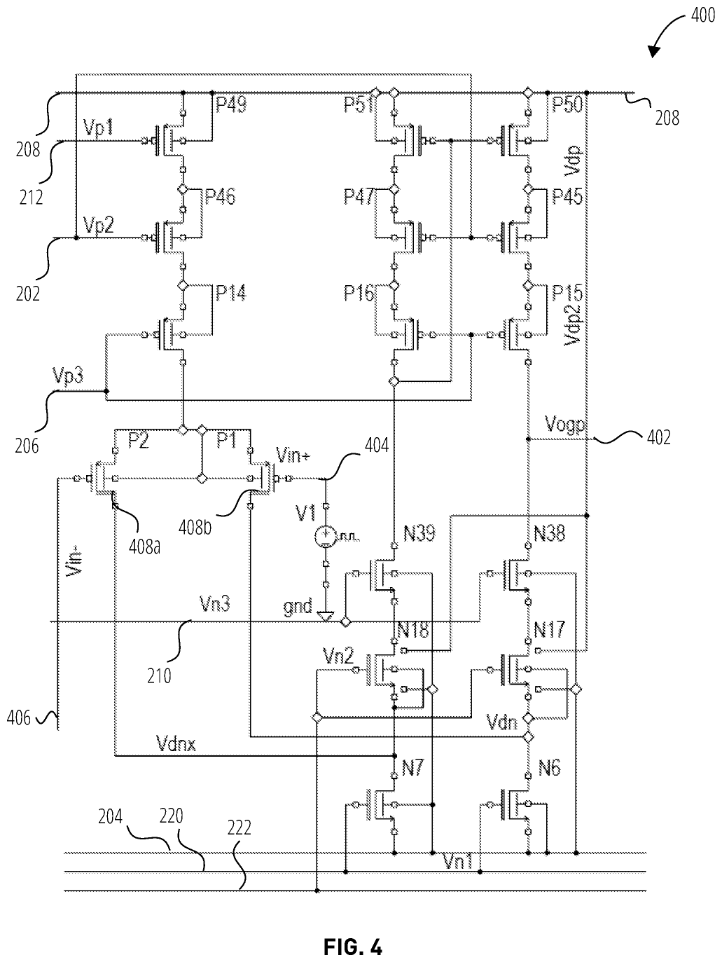

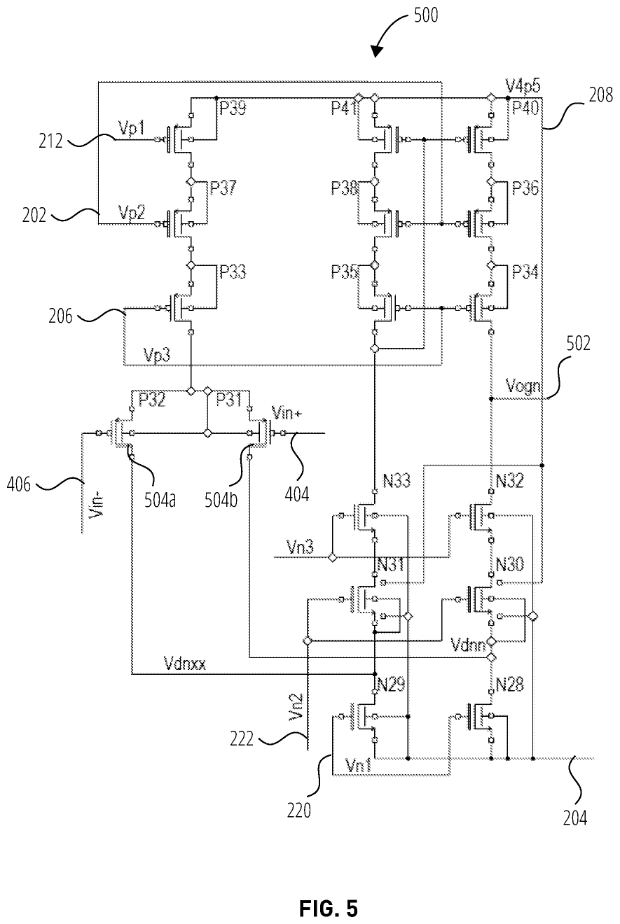

In some examples, biasing is established with a PTAT (proportional to absolute temperature) current feed provided by a delta V_{BE} circuit (not shown) commonly used to implement a band gap reference voltage. The PTAT current is fed and/or replicated to resistors (such as lower resistors R12 224, R7 226, R5 228, R4 230, and upper resistors R6 238, R8 236, R35 234, R37 232, R30 242) and establishes drain currents through feedback (by setting V_{GS}) to produce the desired bias voltages for the current sources 216, 218 and the cascode transistors of the first folded double cascode stage 400 and second folded double cascode stage 500. This establishes the V_{DS} (drain to source voltage) of the common gate (cascode) transistors (e.g., transistors N17, N18 and P45, P47 in FIGS. 4 and N30, N31 and P36, P38 in FIG. 5) and the bias (common source/current source) transistors (e.g., transistors N6, N7 and P50, P51 in FIGS. 4 and N28, N29 and P40, P41 in FIG. 5) of the cascode stages 400, 500 to be PTAT, and accurately sets their voltages to approximately between 4 and 5 thermal voltages (e.g., 4×kT/q≃120-130 mV), assuring that the transistors are saturated (high gain) in weak inversion and assuring that the V_{DS} of transistors P15 and N32 are maintained above 4-5 thermal voltages.

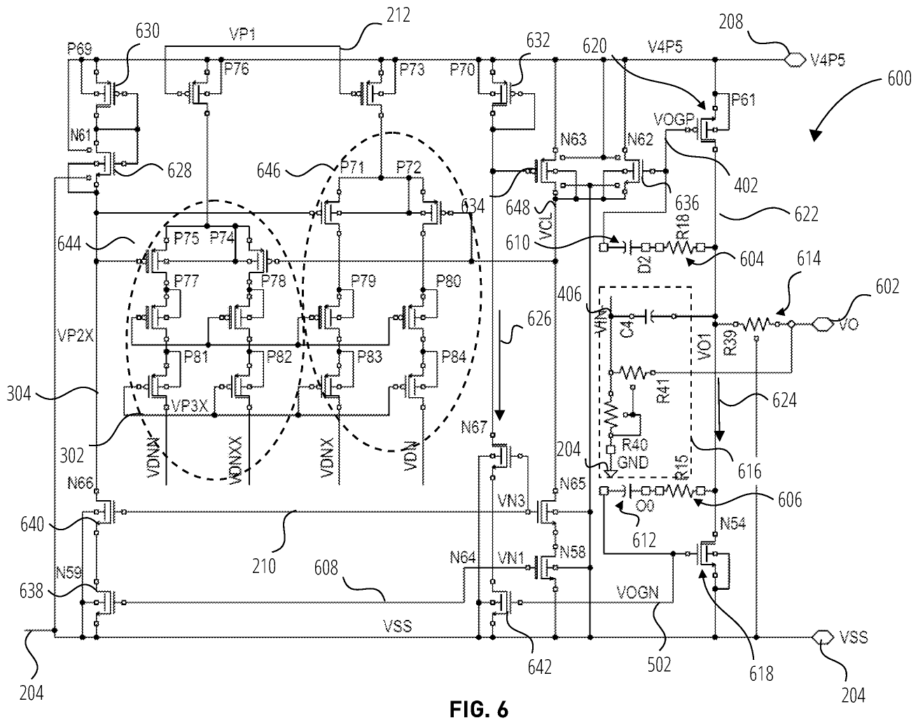

The illustrated example left biasing block 200 includes a first voltage source 214. The left biasing block 200 shares several nodes with one or more other stages of the amplifier circuit 100, including nodes V4p5 208 (separated from ground 240 by first voltage source 214 and therefore corresponding to the positive voltage supply in the illustrated example), Vp1 212, Vp2 202, Vp3 206, Vn1 608 (shown in FIG. 6), Vn2 222, V_{SS} 204, and Vn3 210. In some examples, V_{SS} 204 is connected to ground 240.

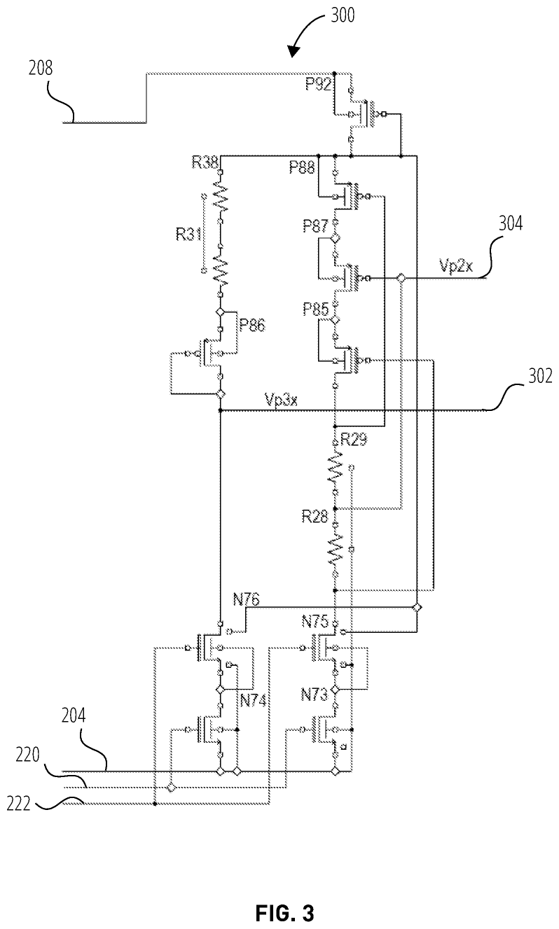

FIG. 3 shows an example right biasing block 300 of the amplifier circuit 100. The illustrated example right biasing block 300 shares several nodes with one or more other stages of the amplifier circuit 100, including nodes V4p5 208, Vp2x 304, Vp3x 302, Vn1 608, Vn2 222, and V_{SS} 204.

FIG. 4 shows an example first folded double cascode stage 400. The first folded double cascode stage 400 is configured to receive a differential input signal (Vin+ 404 and Vin− 406) at a first pair of input transistors 408a, 408b (shown as a pair of PMOS transistors in the illustrated example) and generate a first drive signal Vogp 402 based on the differential input signal. The first drive signal Vogp 402 is used to drive an output transistor of the output stage 600, as described below.

In some examples, the approximate voltage gain of the illustrated double cascode folded input stage is approximately 200,000: (gₘ×r₀)³≃200,000. In some examples, the approximate voltage gain of the illustrated double cascode folded input stage is greater than 200,000, such as approximately 400,000 or 500,000. Some examples may implement a gain smaller than 200,000, but this may reduce the effectiveness of the design in some contexts. In some examples, the outputs of the first folded double cascode stage 400 and second folded double cascode stage 500 (shown in FIG. 5) have double cascoded current mirror loads, which drive the gates of the two output transistors of the output stage 600 (shown in FIG. 6), and represent the first high impedance nodes in their respective paths, as described below with reference to FIG. 6.

The illustrated example first folded double cascode stage 400 shares several nodes with one or more other stages of the amplifier circuit 100, including nodes V4p5 208, Vp1 212, Vp2 202, Vp3 206, Vn3 210, Vn1 608 (shown in FIG. 6), Vn2 222, V_{SS} 204, the differential input signal (Vin+ 404 and Vin− 406), and the first drive signal Vogp 402.

FIG. 5 shows an example second folded double cascode stage 500. The illustrated example second folded double cascode stage 500 is substantially similar to the first folded double cascode stage 400, but is configured to receive the differential input signal (Vin+ 404 and Vin− 406) at a second pair of input transistors 504a, 504b (shown as a pair of PMOS transistors in the illustrated example) and generate a second drive signal Vogn 502 based on the differential input signal. The second drive signal Vogn 502 is used to drive a separate, different output transistor of the output stage 600, as described below.

In some examples, the first folded double cascode stage 400 and second folded double cascode stage 500 (when combined with the PMOS common-source output transistor 620 and NMOS common-source output transistor 618 of output stage 700, described below) jointly implement an equal number of gain stages for positive and negative output signals.

The illustrated example second folded double cascode stage 500 shares several nodes with one or more other stages of the amplifier circuit 100, including nodes V4p5 208, Vp1 212, Vp2 202, Vp3 206, Vn3 210, Vn1 608, Vn2 222, the differential input signal (Vin+ 404 and Vin− 406), and the second drive signal Vogn 502.

It will be appreciated that the various transistors shown as PMOS and NMOS transistors in the double cascode stages 400, 500 can be reversed in some examples (i.e., all PMOS transistors replaced with NMOS transistors and vice versa) having a different common-mode input voltage range. For example, whereas the illustrated example uses PMOS input transistors for the input transistors 408a, 408b (shown in FIG. 4) 504a, 504b, in some examples NMOS input transistors could be used with corresponding modifications to the other transistors of the double cascode stages 400, 500.

FIG. 6 shows an example output stage 600. The illustrated output stage 600 includes a PMOS common-source output transistor 620 driven by the first drive signal Vogp 402 and an NMOS common-source output transistor 618 driven by the second drive signal Vogn 502. The PMOS common-source output transistor 620 and NMOS common-source output transistor 618 jointly form a push-pull output stage configured to generate an output signal at node Vo 602.

In some examples, the output stage 600 is compensated with one or more zero setting resistors (shown as first zero setting resistor 604 and second zero setting resistor 606) in series with the one or more pole splitting capacitors (shown as first pole splitting capacitor 610 and second pole splitting capacitor 612) for performing Miller compensation. In some examples, a relatively small output resistor 614 is also included for driving large capacitive loads of a load capacitor (not shown), such as a load capacitor having a capacitance between 100 pF and 100 μF. The output resistor 614 forms a zero with the load capacitor. In some examples, output resistor 614 may have a value in the range of 0.1 to 1 ohm for a load capacitance of 0.1 μF to 100 μF, and 10-1000 ohms for a load capacitance of 100 pF to 10 nF.

In some examples, the output stage 600 also includes a global feedback loop 616. The global feedback loop 616 sets the closed loop gain for the amplifier. It will be appreciated that the illustrated example global feedback loop 616 could be replaced in different examples with different feedback networks.

In some examples, the output stage 600 includes a translinear class AB regulating loop, such as a translinear harmonic mean regulating loop, which may include: the reference voltage created by P69 630, N61 628 and the bias/drain current from N59 638 and N66 640; sense transistors P61 (i.e. PMOS common-source output transistor 620) and N54 (i.e. NMOS common-source output transistor 618)/N64 642/P70 632; transistors N63 634 and N62 636, and control (high-gain) amplifiers P75, P74 (cascoded by P77, P78, P81, P82, collectively 644) and P71, P72 (cascoded by P79, P80, P83, P84, collectively 646) in conjunction with the two double folded cascode stages 400, 500. In some examples, the translinear class AB regulating loop provides a regulating amplifier that makes VCL 648 substantially equal to Vp2x 304.

A first path through the amplifier circuit 100 is defined from the differential input signal (Vin+ 404 and Vin− 406), through the first pair of input transistors 408a of first folded double cascode stage 400, to the first drive signal Vogp 402, through the PMOS common-source output transistor 620, to the output signal at node Vo 602. A second path through the amplifier circuit 100 is defined from the differential input signal (Vin+ 404 and Vin− 406), through the second pair of input transistors 504a of second folded double cascode stage 500, to the second drive signal Vogn 502, through the NMOS common-source output transistor 618, to the output signal at node Vo 602.

In some examples, the first high impedance node in each of the two paths is the drive signal: Vogn 502 for the first path and Vogp 402 for the second path. The second high impedance node in each path is the output node Vo 602. In some examples, the two high-impedance nodes each have higher impedance than any other nodes in their respective paths.

In some examples, the first pole splitting capacitor 610 and second pole splitting capacitor 612 each have a capacitance of approximately 1 picofarad (pF), and the first zero setting resistor 604 and second zero setting resistor 606 each have a resistance of approximately 10 kiloohms (kΩ). In some examples, these values may be different, and/or the pole splitting capacitors and/or zero setting resistors may be omitted.

In some examples, the set of equations below characterizes the voltages and currents present in output stage 600 when VCL 648 is set equal to Vp2x 304, as described above.

The voltage from source to gate (V_{SG}) of transistor P69 630 plus the voltage from gate to source (V_{GS}) of transistor N61 628 is equal to the bias voltage V_{bias} between nodes V4p5 208 and Vp2x 304.

Current Id61 622 times (x) times current Id58 626=current Id54 624 times (1−x) times current Id58 626=C1 at a given temperature and process realization.

Given x=0.5, current Id61 622=current Id54 624=2C1 divided by current Id58 626=bias current I_{bias}.

As current Id61 622 increases, x approaches zero, and current Id54 624 approaches C1 divided by current Id58 626=I_{bias} divided by 2.

As current Id54 624 increases, x approaches 1, and current Id61 622 approaches C1 divided by current Id58 626=I_{bias} divided by 2.

V_{SG} of transistor P70 632+V_{GS} of transistor N63 634=V_{SG} of PMOS common-source output transistor P61 620+V_{GS} of transistor N62 636=V_{SG} of transistor P69 630+V_{GS} of transistor N61 628=V_{bias}.

The use of double cascode stages 400, 500 may require precise, accurate biasing to be set by the left biasing block 200 and/or right biasing block 300. The biasing is preferably PTAT in some examples in order to maintain the cascoded transistors in saturation while also using a low offset voltage, as described in further detail below. For example, the voltage from V4p5 208 to Vogp 402, across transistors P50+P45+P15 shown in FIG. 4, may be as small as 400 mV in some examples. Similarly, the voltage from V_{SS} 204 to Vogn 502, across transistors N32+N30+N28 shown in FIG. 5, may be as small as 400 mV in some examples. Otherwise, the V_{DS} of said transistors may become too small (e.g., less than 100 mV), causing said transistors to become non-saturated (in the triode region or near the knee voltage), thereby lowering the voltage gain of the amplifier (e.g., by lowering the output resistance of the transistors).

It will be appreciated that, in the illustrated example, V4p5 208 corresponds to a positive voltage supply, Vo 602 corresponds to the output signal, and V_{SS} 204 corresponds to a negative voltage supply. The PMOS common-source output transistor 620 and NMOS common-source output transistor 618 implement a push-pull output stage between the positive voltage supply V4p5 208 and the negative voltage supply V_{SS} 204 to generate the output signal Vo 602.

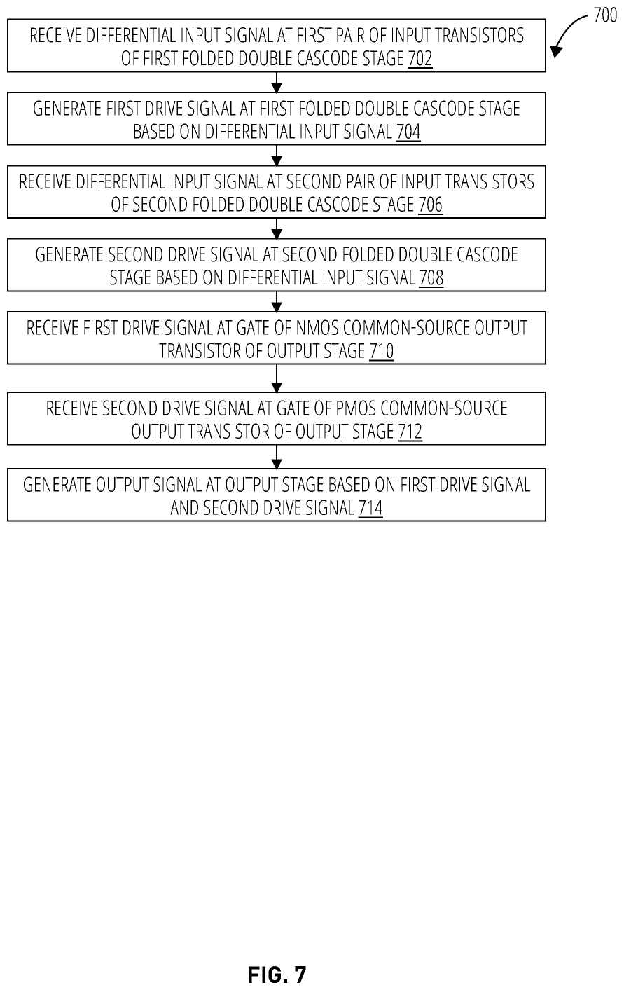

FIG. 7 shows operations of a method 700 of amplifying a differential input signal, using an amplifier circuit 100 as described herein. At operation 702, amplifier circuit 100 receives the differential input signal (Vin+ 404, Vin− 406) at a first pair of input transistors 408a, 408b of a first folded double cascode stage 400. At operation 704, amplifier circuit 100 generates a first drive signal (e.g., Vogp 402) at the first folded double cascode stage 400 based on the differential input signal. At operation 706, amplifier circuit 100 receives the differential input signal at a second pair of input transistors 504a, 504b of a second folded double cascode stage 500. At operation 708, method 700 generates a second drive signal (e.g., Vogn 502) at the second folded double cascode stage 500 based on the differential input signal. At operation 710, amplifier circuit 100 receives the first drive signal Vogp 402 at a gate of an NMOS common-source output transistor 618 of an output stage 600. At operation 712, amplifier circuit 100 receives the second drive signal Vogn 502 at a gate of a PMOS common-source output transistor 620 of the output stage 600. At operation 714, amplifier circuit 100 generates an output signal Vo 602 at the output stage 600 based on the first drive signal Vogp 402 and the second drive signal Vogn 502.

The examples described herein may address one or more technical problems, including but not limited to those identified herein. First, the amplifier circuit 100 may provide a high voltage gain amplifier, such as an amplifier with voltage amplification greater than 200,000 (Av>200,000). Second, the amplifier circuit 100 may provide a low input offset voltage amplifier, such as an amplifier with input offset voltage less than 100 microvolts (<100 μV). Third, the class AB output stage 600 may provide an output stage having low bias current and large peak current capability on demand. Fourth, the amplifier circuit 100 may provide an equal number of gain stages for positive and negative output signals, thereby providing approximately equally high gain for both positive and negative signal swings. Fifth, the amplifier circuit 100 may provide an amplifier with two high impedance nodes in the signal path, thereby facilitating easy, stable compensation and the ability to drive a large capacitive load. Sixth, the amplifier circuit 100 may provide an amplifier with approximately (e.g., at least 90%) rail-to-rail output voltage swing, such as V_{DD} to ground or V_{SS} to a common source output stage. In some examples, the amplifier circuit 100 can achieve an input offset voltage of approximately 50 μV and a voltage gain of >1,000,000 with a high impedance load. In some such examples, in order to achieve an input offset voltage of 100 μV over temperature variations (e.g., 0° C. to 85° C.) and process and power supply variations, the input offset voltage needs to be below 100 μV to start with.

Thus, in a first example, an amplifier circuit is provided that includes a first folded double cascode stage configured to receive a differential input signal at a first pair of input transistors and generate a first drive signal. The amplifier circuit also includes a second folded double cascode stage configured to receive the differential input signal at a second pair of input transistors and generate a second drive signal. The amplifier circuit also includes an output stage, which includes a PMOS common-source output transistor configured to receive the first drive signal at its gate, and an NMOS common-source output transistor configured to receive the first drive signal at its gate, the PMOS common-source output transistor and NMOS common-source output transistor being jointly configured to generate an output signal based on the first drive signal and the second drive signal.

In a second example that includes the features of the first example, the amplifier circuit may also include at least one biasing stage configured to apply bias voltages to one or more transistors of each of the first folded double cascode stage and the second folded double cascode stage.

In a third example that includes the features of the first example and may include the features of the second example, the amplifier circuit may also include where the output stage further includes a translinear class AB regulating loop.

In a fourth example that includes the features of the first example and may include the features of the second example and/or third example, the amplifier circuit may also include where the first folded double cascode stage and second folded double cascode stage are operative to apply a voltage gain of greater than 180,000 to the differential input signal to generate the first drive signal and the second drive signal.

In a fifth example that includes the features of the first example and optionally the features of one or more of the second through fourth examples, the first drive signal and the second drive signal comprise double cascoded current mirror loads.

In a sixth example that includes the features of the first example and may include the features of one or more of the second through fifth examples, the amplifier circuit may also include where the first drive signal and the output signal comprise a first and second high impedance node, respectively, of a first path, the first and second high impedance nodes having higher impedance than any other nodes in the first path, and the second drive signal and the output signal comprise a first and second high impedance node, respectively, of a second path, the first and second high impedance nodes having higher impedance than any other nodes in the second path.

In a seventh example that includes the features of the first example and may include the features of one or more of the second through sixth examples, the amplifier circuit may also include where the output stage further includes one or more pole splitting capacitors configured to perform Miller compensation, and one or more zero setting resistors in series with the one or more pole splitting capacitors.

In an eighth example that includes the features of the first example and may include the features of one or more of the second through seventh examples, the amplifier circuit may also include where the amplifier circuit applies a voltage amplification of greater than 200,000 to the differential input signal to generate the output signal.

In a ninth example that includes the features of the first example and may include the features of one or more of the second through seventh examples, the amplifier circuit may also include where the amplifier circuit has a deterministic input offset voltage of less than 100 microvolts.

In a tenth example that includes the features of the first example and may include the features of one or more of the second through seventh examples, the amplifier circuit may also include the output stage has a low bias current and a large peak current capability.

In an eleventh example that includes the features of the first example and may include the features of one or more of the second through seventh examples, the amplifier circuit may also include where an output voltage swing of the output signal is within 100 millivolts of a rail-to-rail voltage of a V_{DD} to a ground.

In a twelfth example that includes the features of the first example and may include the features of one or more of the second through seventh examples, the amplifier circuit may also include where an output voltage swing of the output signal is within 100 millivolts of a rail-to-rail voltage of a V_{SS} to a common source output stage. Other technical features may be readily apparent to one skilled in the art from the following figures, descriptions, and claims.

In a thirteenth example that includes the features of the first example and may include the features of one or more of the second through seventh examples, the amplifier circuit may also include where the at least one biasing stage is configured to receive a proportional to absolute temperature (PTAT) current feed from a delta V_{BE} circuit.

In a fourteenth example that includes the features of the first example and may include the features of one or more of the second through seventh examples, the amplifier circuit may also include where the bias voltages are operative to establish a V_{DS} between 4 and 5 thermal voltages for one or more common-gate transistors and one or more common-source transistors of the first folded double cascode stage, and one or more common-gate transistors and one or more common-source transistors of the second folded double cascode stage.

In a fifteenth example that includes the features of the first example and may include the features of one or more of the second through seventh examples, the amplifier circuit may also include where the amplifier circuit includes an equal number of gain stages for positive and negative output signals.

In a sixteenth example that includes the features of the first example and may include the features of one or more of the second through seventh examples, the amplifier circuit may also include where the translinear class AB regulating loop includes a translinear harmonic mean regulating loop.

In a seventeenth example that includes the features of the first example and may include the features of one or more of the second through seventh examples, the amplifier circuit may also include where the amplifier circuit drives a capacitive load of load capacitor having capacitance between 100 pF and 100 μF, and the output stage further comprises an output resistor forming a zero with the load capacitor.

In a eighteenth example, a method of amplifying a differential input signal is provided that includes receiving the differential input signal at a first pair of input transistors of a first folded double cascode stage, generating a first drive signal at the first folded double cascode stage based on the differential input signal, receiving the differential input signal at a second pair of input transistors of a second folded double cascode stage, generating a second drive signal at the second folded double cascode stage based on the differential input signal, receiving the first drive signal at a gate of a NMOS common-source output transistor of an output stage, receiving the second drive signal at a gate of a PMOS common-source output transistor of the output stage, and generating an output signal at the output stage based on the first drive signal and the second drive signal.

In a nineteenth example that includes the features of the eighteenth example, the method may also include applying bias voltages to one or more transistors of each of the first folded double cascode stage and the second folded double cascode stage using at least one biasing stage.

In a twentieth example that includes the features of the eighteenth example and may include the features of the nineteenth example, the method may also include regulating the output stage using a translinear class AB regulating loop. Other technical features may be readily apparent to one skilled in the art from the following figures, descriptions, and claims.

In the examples described above, the input terminal and output terminal of the amplifier circuit include one or more transistors. For example, the input terminal may be the gate of one or more CMOS transistors, and the output terminal is an inverting common terminal implemented as the source of a CMOS transistor. However, in other examples, the input terminal and/or inverting common terminal are implemented using other technologies, such as silicon or non-silicon bipolar technologies or GaAs semiconductors, as described above.

What is claimed is:

1. An amplifier circuit comprising:
a first folded double cascode stage configured to receive a differential input signal at a first pair of input transistors and generate a first drive signal;
a second folded double cascode stage configured to receive the differential input signal at a second pair of input transistors and generate a second drive signal; and
an output stage comprising:
a PMOS common-source output transistor configured to receive the first drive signal at its gate; and
an NMOS common-source output transistor configured to receive the second drive signal at its gate;
the PMOS common-source output transistor and NMOS common-source output transistor being jointly configured to generate an output signal based on the first drive signal and the second drive signal.

2. The amplifier circuit of claim 1, further comprising:
at least one biasing stage configured to apply bias voltages to one or more transistors of each of the first folded double cascode stage and the second folded double cascode stage.

3. The amplifier circuit of claim 2, wherein:
the at least one biasing stage is configured to receive at least one proportional to absolute temperature (PTAT) current feed from a delta V_{BE} circuit.

4. The amplifier circuit of claim 3, wherein:
the bias voltages are operative to establish a V_{DS} between 4 and 5 thermal voltages for:
one or more common-gate transistors and one or more common-source transistors of the first folded double cascode stage; and
one or more common-gate transistors and one or more common-source transistors of the second folded double cascode stage.

5. The amplifier circuit of claim 2, further comprising:
an equal number of gain stages for positive and negative output signals.

6. The amplifier circuit of claim 1, wherein:
the output stage further comprises a translinear class AB regulating loop.

7. The amplifier circuit of claim 6, wherein the translinear class AB regulating loop comprises a translinear harmonic mean regulating loop.

8. The amplifier circuit of claim 1, wherein:
the first folded double cascode stage and second folded double cascode stage are operative to apply a voltage gain of greater than 180,000 to the differential input signal to generate the first drive signal and the second drive signal.

9. The amplifier circuit of claim 1, wherein:
the first drive signal and the second drive signal comprise double cascoded current mirror loads.

10. The amplifier circuit of claim 1, wherein:
the first drive signal and the output signal comprise a first and second high impedance node, respectively, of a first path, the first and second high impedance nodes having higher impedance than any other nodes in the first path; and
the second drive signal and the output signal comprise the first and second high impedance node, respectively, of a second path, the first and second high impedance nodes having higher impedance than any other nodes in the second path.

11. The amplifier circuit of claim 1, wherein the output stage further comprises:
one or more pole splitting capacitors configured to perform Miller compensation; and
one or more zero setting resistors in series with the one or more pole splitting capacitors.

12. The amplifier circuit of claim 11, wherein:
the amplifier circuit drives a capacitive load of load capacitor having capacitance between 100 pF and 100 μF; and
the output stage further comprises an output resistor forming a zero with the load capacitor.

13. The amplifier circuit of claim 1, wherein:
the amplifier circuit applies a voltage amplification of greater than 200,000 to the differential input signal to generate the output signal.

14. The amplifier circuit of claim 1, wherein:
the amplifier circuit has a deterministic input offset voltage of less than 100 microvolts.

15. The amplifier circuit of claim 1, wherein the output stage has:
a bias current between 15 microamps and 150 microamps; and
a peak current capability between 30 milliamps and 300 milliamps.

16. The amplifier circuit of claim 1, wherein:
an output voltage swing of the output signal is within 100 millivolts of a rail-to-rail voltage of a V_{DD} to a ground.

17. The amplifier circuit of claim 1, wherein:
an output voltage swing of the output signal is within 100 millivolts of a rail-to-rail voltage of a V_{SS} to the output signal.

18. A method of amplifying a differential input signal, comprising:
receiving the differential input signal at a first pair of input transistors of a first folded double cascode stage;
generating a first drive signal at the first folded double cascode stage based on the differential input signal;
receiving the differential input signal at a second pair of input transistors of a second folded double cascode stage;
generating a second drive signal at the second folded double cascode stage based on the differential input signal;
receiving the first drive signal at a gate of a NMOS common-source output transistor of an output stage;
receiving the second drive signal at a gate of a PMOS common-source output transistor of the output stage; and
generating an output signal at the output stage based on the first drive signal and the second drive signal.

19. The method of claim 18, further comprising:
applying bias voltages to one or more transistors of each of the first folded double cascode stage and the second folded double cascode stage using at least one biasing stage.

20. The method of claim 18, further comprising:
regulating the output stage using a translinear class AB regulating loop.
